(19) United States
(12) Patent Application Publication
(10) Pub. No.: US 2014/0329349 A1
(43) Pub. Date: Nov. 6, 2014

(54) ORGANIC LAYER DEPOSITION APPARATUS, AND METHOD OF MANUFACTURING ORGANIC LIGHT-EMITTING DISPLAY APPARATUS BY USING THE SAME

(71) Applicant: Samsung Display Co., Ltd., Yongin-City (KR)

(72) Inventor: Sung-Ho Seo, Yongin-City (KR)

(73) Assignee: Samsung Display Co., Ltd., Yongin-City (KR)

(21) Appl. No.: 14/078,471

(22) Filed: Nov. 12, 2013

(30) Foreign Application Priority Data
May 2, 2013 (KR) 10-2013-0049623

(51) Int. Cl. H01L 51/56

(52) U.S. Cl. CPC H01L 51/56
USPC 438/34; 118/720

(57) ABSTRACT

An organic layer deposition apparatus includes a conveyer unit including a transfer unit, a first conveyer unit, and a second conveyer unit; and a deposition unit including one or more organic layer deposition assemblies for depositing an organic layer on a substrate attached to the transfer unit. Each of the one or more organic layer deposition assemblies includes: a plurality of deposition sources for discharging a deposition material; a deposition source nozzle unit including a plurality of deposition source nozzles; a patterning slit sheet including a plurality of patterning slits; and a plurality of source shutters separated from the plurality of deposition sources, respectively, and blocking a deposition material that is vaporized in each of the plurality of deposition sources. The plurality of source shutters move in different directions, thereby blocking or allowing to pass the deposition material.

### CROSS-REFERENCE TO RELATED APPLICATION

This application claims priority to and the benefit of Korean Patent Application No. 10-2013-0049623, filed on May 2, 2013, in the Korean Intellectual Property Office, the disclosure of which is incorporated herein in its entirety by reference.

### BACKGROUND

1. Field

Embodiments according to the present invention relate to an organic layer deposition apparatus, and a method of manufacturing an organic light-emitting display apparatus by using the organic layer deposition apparatus.

2. Description of the Related Art

Organic light-emitting display devices have wider viewing angles, better contrast characteristics, and faster response speeds than other display devices, and thus have drawn attention as a next-generation display device.

An organic light-emitting display device includes intermediate layers (including an emission layer) arranged between a first electrode and a second electrode. The electrodes and the intermediate layers may be formed using various methods, one of which is an independent deposition method. When an organic light-emitting display device is manufactured by using the deposition method, a fine metal mask (FMM) having the same pattern as that of an organic layer to be formed is positioned to closely contact a substrate on which the organic layer and the like are formed, and an organic layer material is deposited through the FMM to form the organic layer having the desired pattern.

However, the deposition method using such an FMM presents difficulties in manufacturing larger organic light-emitting display devices using a large mother glass. For example, when such a large mask is used, the mask may bend due to its own weight, thereby distorting a pattern. Such disadvantages are not conducive to the recent trend towards high-definition patterns.

Moreover, processes of aligning a substrate and an FMM to closely contact each other, performing deposition thereon, and separating the FMM from the substrate are time-consuming, resulting in a long manufacturing time and low production efficiency.

Information disclosed in this Background section was known to the inventors of the present invention before achieving the present invention or is technical information acquired in the process of achieving the present invention. Therefore, it may contain information that does not form the prior art or information that was not already known in this country to a person of ordinary skill in the art prior to the time the present invention was made by the inventors.

### SUMMARY

Embodiments according to the present invention provide an organic layer deposition apparatus that is easily manufactured, that is suitable for use in the mass production of a large substrate, and that enables high-definition patterning, and a method of manufacturing an organic light-emitting display apparatus by using the organic layer deposition apparatus.

According to an aspect of embodiments of the present invention, there is provided an organic layer deposition apparatus including a conveyer unit including a transfer unit for attaching a substrate and configured to move along with the substrate, a first conveyer unit for moving in a first direction the transfer unit to which the substrate is attached, and a second conveyer unit for moving in a direction opposite to the first direction the transfer unit from which the substrate is separated after deposition has been completed; and a deposition unit including one or more organic layer deposition assemblies for depositing an organic layer on the substrate that is attached to the transfer unit, wherein each of the one or more organic layer deposition assemblies includes: a plurality of deposition sources for discharging a deposition material; a deposition source nozzle unit at a side of each of the plurality of deposition sources and including a plurality of deposition source nozzles; a patterning slit sheet facing the deposition source nozzle unit and including a plurality of patterning slits; and a plurality of source shutters separated from the plurality of deposition sources, respectively, and blocking a deposition material that is vaporized in each of the plurality of deposition sources, and wherein the plurality of source shutters move in different directions, thereby blocking or allowing to pass the deposition material that is vaporized in each of the plurality of deposition sources.

The plurality of deposition sources may include a first deposition source; a second deposition source that is separated from the first deposition source; and a third deposition source that is separated from the second deposition source.

The plurality of source shutters may include a first source shutter that is configured to be located above the first deposition source; a second source shutter that is configured to be located above the second deposition source; and a third source shutter that is configured to be located above the third deposition source.

The first source shutter and the third source shutter may be movable in opposite directions.

The second source shutter may be movable in a direction perpendicular to a movement direction of at least one of the first source shutter or the third source shutter.

The plurality of source shutters may move in a space between the plurality of deposition sources and the patterning slit sheet.

The deposition material that is discharged from the plurality of deposition sources may pass through the patterning slit sheet and then may be deposited to form a pattern on the substrate.

The patterning slit sheet may be smaller than the substrate in the first direction.

The first conveyer unit and the second conveyer unit may pass through the deposition unit.

The first conveyer unit and the second conveyer unit may be respectively arranged above and below in parallel to each other.

The transfer unit may be configured to cyclically move between the first conveyer unit and the second conveyer unit, and to keep the substrate attached thereto, spaced apart from the organic layer deposition assembly while being transferred by the first conveyer unit.

According to another aspect of embodiments of the present invention, there is provided a method of manufacturing an organic light-emitting display apparatus by using an organic layer deposition apparatus for forming an organic layer on a substrate, the method including: transporting, into a chamber, a transfer unit to which the substrate is attached, by using a first conveyer unit passing through the chamber; forming an organic layer by depositing a deposition material discharged from an organic layer deposition assembly on the substrate while the substrate is moved relative to the organic layer deposition assembly with the organic layer deposition assembly in the chamber being spaced apart from the substrate; and transporting the transfer unit from which the substrate is separated, by using a second conveyer unit passing through the chamber, wherein the organic layer deposition assembly includes a plurality of deposition sources for discharging a deposition material; and a plurality of source shutters separated from the plurality of deposition sources, respectively, and blocking a deposition material that is vaporized in each of the plurality of deposition sources, and wherein, in the forming of the organic layer, the plurality of source shutters move in different directions, whereby the plurality of source shutters block or allow to pass the deposition material that is vaporized in each of the plurality of deposition sources.

The organic layer deposition assembly may further include a deposition source nozzle unit at a side of each of the plurality of deposition sources and including a plurality of deposition source nozzles; and a patterning slit sheet facing the deposition source nozzle unit and including a plurality of patterning slits.

The deposition material that is discharged from the plurality of deposition sources may pass through the patterning slit sheet and then may be deposited to form a pattern on the substrate.

The plurality of source shutters may move in a space between the plurality of deposition sources and the patterning slit sheet.

The plurality of source shutters may be movable to prevent the deposition material, which is vaporized in each of the plurality of deposition sources, from being deposited on the substrate.

The plurality of deposition sources may include a first deposition source; a second deposition source that is separated from the first deposition source; and a third deposition source that is separated from the second deposition source.

The plurality of source shutters may include a first source shutter that is configured to be located above the first deposition source; a second source shutter that is configured to be located above the second deposition source; and a third source shutter that is configured to be located above the third deposition source.

The first source shutter and the third source shutter may be movable in opposite directions.

The second source shutter may be movable in a direction perpendicular to a movement direction of at least one of the first source shutter or the third source shutter.

### BRIEF DESCRIPTION OF THE DRAWINGS

The above and other features and aspects of the present invention will become more apparent by describing in detail exemplary embodiments thereof with reference to the attached drawings in which:

FIG. 1 is a schematic plan view illustrating a structure of an organic layer deposition apparatus according to an embodiment of the present invention;

FIG. 2 is a schematic side view of a deposition unit of the organic layer deposition apparatus of FIG. 1, according to an embodiment of the present invention;

FIG. 3 is a schematic perspective view of the deposition unit of the organic layer deposition apparatus of FIG. 1, according to an embodiment of the present invention;

FIG. 4 is a conceptual diagram of the organic layer deposition assembly of FIG. 3, according to an embodiment of the present invention;

FIG. 5 is a conceptual diagram illustrating the deposition source and a source shutter of FIG. 3, according to an embodiment of the present invention;

FIG. 6 is a conceptual diagram illustrating operational statuses of the deposition source and the source shutter of FIG. 5;

FIG. 7 is a conceptual diagram illustrating operational statuses of the deposition source and the source shutter of FIG. 5;

FIG. 8 is a schematic perspective view of an organic layer deposition assembly, according to another embodiment of the present invention; and

FIG. 9 is a cross-sectional view of an active matrix-type organic light-emitting display device manufactured using the organic layer deposition apparatus, according to an embodiment of the present invention.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those of ordinary skill in the art. The terms or words used in the following description should not be construed as limiting the spirit and scope of the following claims but should be construed as describing the present invention. Throughout the specification, a singular form may include plural forms, unless there is a particular description contrary thereto. Also, terms such as “comprise” or “comprising” are used to specify existence of a recited component, a process, an operation, and/or an element, not excluding the existence of one or more other recited components, one or more other processes, one or more other operations, and/or one or more other elements. While terms “first” and “second” are used to describe various components, it is obvious that the components are not limited to the terms “first” and “second”. The terms “first” and “second” are used only to distinguish between each component.

As used herein, the term “and/or” includes any and all combinations of one or more of the associated listed items. Expressions such as “at least one of,” when preceding a list of elements, modify the entire list of elements and do not modify the individual elements of the list.

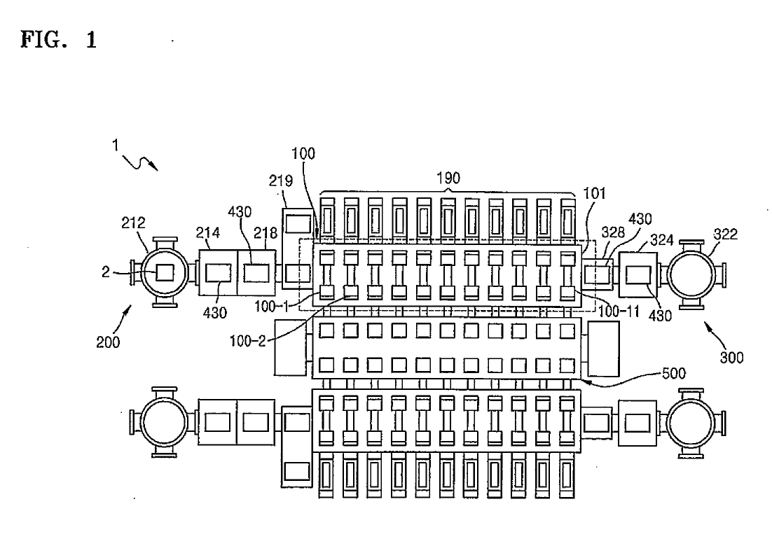

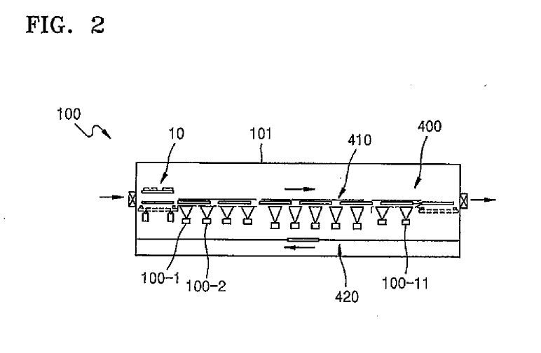

FIG. 1 is a schematic plan view illustrating a structure of an organic layer deposition apparatus 1 according to an embodiment of the present invention. FIG. 2 is a schematic side view of a deposition unit 100 of the organic layer deposition apparatus 1 of FIG. 1, according to an embodiment of the present invention.

Referring to FIGS. 1 and 2, the organic layer deposition apparatus 1 includes the deposition unit 100, a loading unit 200, an unloading unit 300, and a conveyer unit 400.

The loading unit 200 may include a first rack 212, a transport chamber 214, a first inversion chamber 218, and a buffer chamber 219.

A plurality of substrates 2 onto which a deposition material has not yet been applied are stacked up on the first rack 212. A transport robot included in the transport chamber 214 picks up one of the substrates 2 from the first rack 212, places it on a transfer unit 430 transferred by a second conveyer unit 420, and moves the transfer unit 430 on which the substrate 2 is placed into the first inversion chamber 218.

The first inversion chamber 218 is located adjacent to the transport chamber 214. The first inversion chamber 218 includes a first inversion robot that inverts the transfer unit 430 and then loads it on a first conveyer unit 410 of the deposition unit 100.

Referring to FIG. 1, the transport robot of the transport chamber 214 places one of the substrates 2 on a top surface of the transfer unit 430, and the transfer unit 430, on which the substrate 2 is placed, is then transferred into the first inversion chamber 218. The first inversion robot of the first inversion chamber 218 inverts the transfer unit 430 so that the substrate 2 is turned upside down in the deposition unit 100.

The unloading unit 300 is configured to operate in an opposite manner to the loading unit 200 described above. Specifically, a second inversion robot in a second inversion chamber 328 inverts the transfer unit 430, which has passed through the deposition unit 100 while the substrate 2 is placed on the transfer unit 430, and then moves the transfer unit 430, on which the substrate 2 is placed, into an ejection chamber 324. Then, an ejection robot takes the transfer unit 430 on which the substrate 2 is placed out of the ejection chamber 324, separates the substrate 2 from the transfer unit 430, and then loads the substrate 2 on, a second rack 322. The transfer unit 430, from which the substrate 2 is separated, is returned to the loading unit 200 via the second conveyer unit 420.

However, the present invention is not limited to the above example. For example, when placing the substrate 2 on the transfer unit 430, the substrate 2 may be fixed (or attached) onto a bottom surface of the transfer unit 430 and then moved into the deposition unit 100. In such an embodiment, for example, the first inversion robot of the first inversion chamber 218 and the second inversion robot of the second inversion chamber 328 may be omitted.

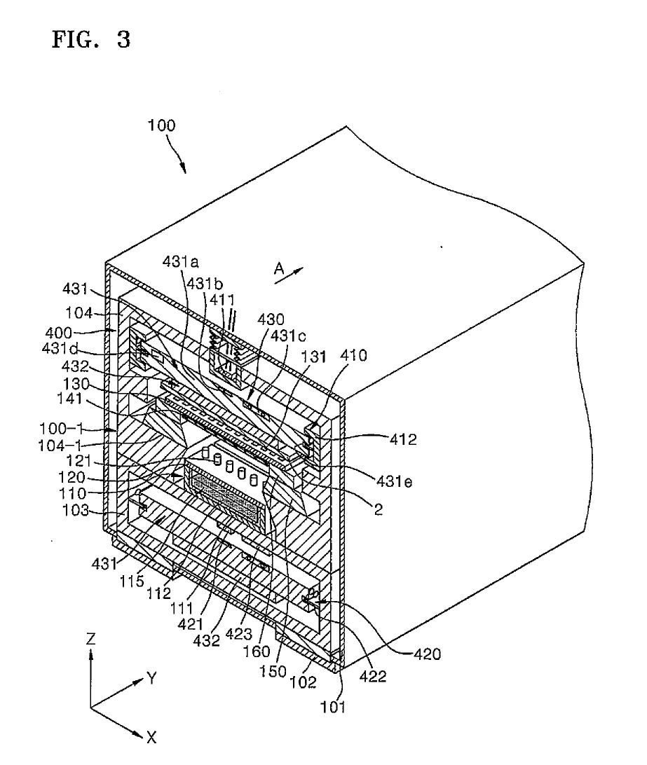

The deposition unit 100 may include at least one chamber for deposition. In one embodiment, the deposition unit 100 includes a chamber 101 in which a plurality of organic layer deposition assemblies 100-1, 100-2, . . . , 100-n may be located. Referring to FIG. 1, 11 organic layer deposition assemblies, i.e., the organic layer deposition assembly 100-1, the organic layer deposition assembly 100-2, through the eleventh organic layer deposition assembly 100-11, are located in the chamber 101, but the number of organic layer deposition assemblies may vary with a desired deposition material 115 (see for example, FIG. 3) and deposition conditions. The chamber 101 is maintained in vacuum during the deposition process. Here, since the organic layer deposition assemblies 100-1 to 100-11 are formed with a same or similar structure, hereinafter, the organic layer deposition assembly 100-1 will be described in detail.

The transfer unit 430 with the substrate 2 fixed thereon may be moved at least to the deposition unit 100 or may be moved sequentially to the loading unit 200, the deposition unit 100, and the unloading unit 300, by the first conveyer unit 410, and the transfer unit 430 from which the substrate 2 is separated in the unloading unit 300 may be moved back to the loading unit 200 by the second conveyer unit 420.

The first conveyer unit 410 passes through the chamber 101 when passing through the deposition unit 100, and the second conveyer unit 420 conveys the transfer unit 430 from which the substrate 2 is separated.

Here, the organic layer deposition apparatus 1 is configured such that the first conveyer unit 410 and the second conveyer unit 420 are respectively located above and below so that after the transfer unit 430, on which deposition has been completed while passing through the first conveyer unit 410, is separated from the substrate 2 in the unloading unit 300, the transfer unit 430 is returned to the loading unit 200 via the second conveyer unit 420 formed below the first conveyer unit 410, and thus the organic layer deposition apparatus 1 may have an improved space utilization efficiency.

In an embodiment, the deposition unit 100 of FIG. 1 may further include a deposition source replacement unit 190 located at a side of each organic layer deposition assembly. Although not particularly illustrated in the drawings, the deposition source replacement unit 190 may be formed as a cassette-type that may be drawn to the outside from each organic layer deposition assembly. Thus, a deposition source 110 (refer to FIG. 3) of the organic layer deposition assembly 100-1 may be easily replaced.

FIG. 1 illustrates one set of two organic layer deposition apparatuses 1 that each consist of the loading unit 200, the deposition unit 100, the unloading unit 300, and the conveyer unit 400. That is, in FIG. 1, two organic layer deposition apparatuses 1 are vertically arranged. In this case, a patterning slit sheet replacement unit 500 may be further arranged between the two organic layer deposition apparatuses 1. That is, because the patterning slit sheet replacement unit 500 is arranged between the two organic layer deposition apparatuses 1, the two organic layer deposition apparatuses 1 jointly use the patterning slit sheet replacement unit 500, so that a space may be further efficiently used, compared to a case in which each of the two organic layer deposition apparatuses 1 has a patterning slit sheet replacement unit 500.

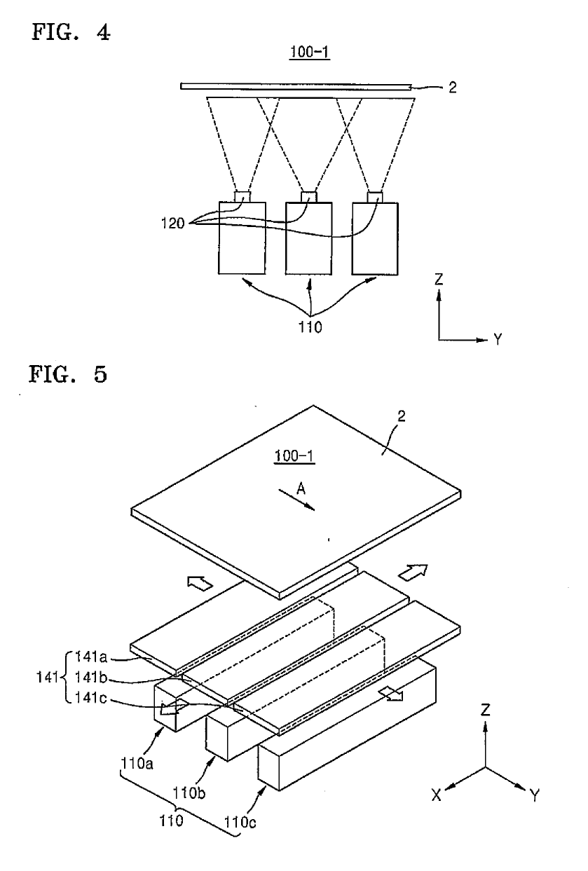

FIG. 3 is a schematic perspective view of the deposition unit 100 of the organic layer deposition apparatus 1 of FIG. 1, according to an embodiment of the present invention. FIG. 4 is a conceptual diagram of the deposition unit 100 of FIG. 3 showing multiple deposition sources 110 along the Y-axis direction, according to an embodiment of the present invention.

Referring to FIG. 3, the deposition unit 100 of the organic layer deposition apparatus 1 includes at least one organic layer deposition assembly 100-1 and the conveyer unit 400.

Hereinafter, an overall structure of the deposition unit 100 will be described.

The chamber 101 may be formed as a hollow box type and accommodate the at least one organic layer deposition assembly 100-1 and the transfer unit 430. In another descriptive manner, a foot 102 is formed so as to fix the deposition unit 100 on the ground, a lower housing 103 is located on the foot 102, and an upper housing 104 is located on the lower housing 103. The chamber 101 accommodates both the lower housing 103 and the upper housing 104. In this regard, a connection part of the lower housing 103 and the chamber 101 is sealed so that the inside of the chamber 101 is completely isolated from the outside. Due to the structure in which the lower housing 103 and the upper housing 104 are located on the foot 102 fixed on the ground, the lower housing 103 and the upper housing 104 may be maintained in a fixed position even though the chamber 101 is repeatedly contracted and expanded. Thus, the lower housing 103 and the upper housing 104 may serve as a reference frame in the deposition unit 100.

The upper housing 104 includes the organic layer deposition assembly 100-1 and the first conveyer unit 410 of the conveyer unit 400, and the lower housing 103 includes the second conveyer unit 420 of the conveyer unit 400. While the transfer unit 430 is cyclically moving between the first conveyer unit 410 and the second conveyer unit 420, a deposition process is continuously performed.

Hereinafter, constituents of the organic layer deposition assembly 100-1 are described in detail.

The organic layer deposition assembly 100-1 includes the deposition source 110, a deposition source nozzle unit 120, a patterning slit sheet 130, a source shutter 141, a first stage 150, a second stage 160, and/or the like. In this regard, all the elements illustrated in FIG. 3 may be arranged in the chamber 101 maintained in an appropriate vacuum state. This structure is used to achieve the linearity of a deposition material.

The substrate 2, on which the deposition material 115 is to be deposited, is arranged in the chamber 101. The substrate 2 may be a substrate for a flat panel display device. For example, a large substrate having a size of at least 40 inches, such as a mother glass for manufacturing a plurality of flat panel displays, may be used as the substrate 2.

Here, the deposition process may be performed with the substrate 2 being moved relative to the organic layer deposition assembly 100-1.

For example, in a conventional deposition method using a fine metal mask (FMM), the size of the FMM is the same as that of a substrate. Thus, as the size of the substrate increases, the size of the FMM also increases. Due to these problems, it is difficult to fabricate the FMM and to align the FMM in a precise pattern by elongation of the FMM.

To address these problems, in the organic layer deposition assembly 100-1 according to the present embodiment, deposition may be performed while the organic layer deposition assembly 100-1 and the substrate 2 are moved relative to each other. In other words, deposition may be continuously performed while the substrate 2, which faces the organic layer deposition assembly 100-1, is moved in a Y-axis direction. That is, deposition is performed in a scanning manner while the substrate 2 is moved in a direction of arrow A illustrated in FIG. 3. Although the substrate 2 is illustrated as being moved in the Y-axis direction in the chamber 101 in FIG. 3 when deposition is performed, the present invention is not limited thereto. For example, deposition may be performed while the organic layer deposition assembly 100-1 is moved in the Y-axis direction and the substrate 2 is held in a fixed position.

Thus, in the organic layer deposition assembly 100-1, the patterning slit sheet 130 may be smaller (e.g., much smaller) than an FMM used in a conventional deposition method. In other words, in the organic layer deposition assembly 100-1, deposition is continuously performed, i.e., in a scanning manner while the substrate 2 is moved in the Y-axis direction. Thus, at least one of the lengths of the patterning slit sheet 130 in X-axis and Y-axis directions may be much less than a length of the substrate 2. Because the patterning slit sheet 130 may be formed smaller (e.g., much smaller) than the FMM used in a conventional deposition method, it is relatively easy to manufacture the patterning slit sheet 130. That is, a small patterning slit sheet 130 is more suitable in view of the manufacturing processes, including etching followed by precise elongation, welding, transferring, and washing processes, than the FMM used in a conventional deposition method. In addition, this is more suitable for manufacturing a relatively large display device.

In order to perform deposition while the organic layer deposition assembly 100-1 and the substrate 2 are moved relative to each other as described above, the organic layer deposition assembly 100-1 and the substrate 2 may be spaced apart from each other by a certain distance (e.g., a gap). This is described below in more detail.

The deposition source 110 that contains and heats the deposition material 115 is located at a side opposite to a facing side in which the substrate 2 is located in the chamber 101. As the deposition material 115 contained in the deposition source 110 is vaporized, deposition is performed on the substrate 2.

In more detail, the deposition source 110 includes a crucible 111 that is filled with the deposition material 115 and a heater 112 that heats the crucible 111 so as to vaporize the deposition material 115 toward a side of the crucible 111 filled with the deposition material 115, in particular, toward the deposition source nozzle unit 120.

The deposition source nozzle unit 120 is located at a side of the deposition source 110 facing the substrate 2. Here, the organic layer deposition assembly 100-1 may include different deposition nozzles in performing deposition for forming common layers and pattern layers.

The patterning slit sheet 130 may be further located between the deposition source 110 and the substrate 2. The patterning slit sheet 130 may further include a frame having a shape similar to a window frame. The patterning slit sheet 130 includes a plurality of patterning slits 131 arranged along the X-axis direction. The deposition material 115 that has been vaporized in the deposition source 110 passes through the deposition source nozzle unit 120 and the patterning slit sheet 130 and is then deposited onto the substrate 2. In this regard, the patterning slit sheet 130 may be formed using the same method as that used to form an FMM, in particular, a stripe-type mask, e.g., etching. In this regard, a total number of patterning slits 131 may be more than a total number of deposition source nozzles 121.

Here, the deposition source 110 (and the deposition source nozzle unit 120 combined thereto) and the patterning slit sheet 130 may be spaced apart from each other by a certain distance (e.g., a gap).

As described above, deposition is performed while the organic layer deposition assembly 100-1 is moved relative to the substrate 2. In order for the organic layer deposition assembly 100-1 to be moved relative to the substrate 2, the patterning slit sheet 130 is spaced apart from the substrate 2 by a certain distance (e.g., a gap).

In a conventional deposition method using an FMM, deposition is typically performed with the FMM in close contact with a substrate in order to prevent formation of shadows on the substrate. However, when the FMM is formed in close contact with the substrate, defects due to the contact between the substrate and the FMM may occur. In addition, because it is difficult to move the mask with respect to the substrate, the mask and the substrate have the same size. Accordingly, the mask becomes larger as the size of a display device increases. However, it is difficult to form a large mask.

To address these problems, in the organic layer deposition assembly 100-1 according to the present embodiment, the patterning slit sheet 130 is formed spaced apart by a certain distance (e.g., a gap) from the substrate 2 on which a deposition material is to be deposited.

According to the present embodiment, deposition may be performed while a mask formed smaller than a substrate is moved with respect to the substrate, and thus, it is relatively easy to manufacture the mask. In addition, defects due to contact between the substrate and the mask may be prevented. In addition, because it is unnecessary to closely contact the substrate with the mask during a deposition process, a manufacturing speed may be improved.

Hereinafter, particular disposition of each element of the upper housing 104 will be described.

First, the deposition source 110 and the deposition source nozzle unit 120 are located at a bottom portion of the upper housing 104. Accommodation portions 104-1 are respectively formed on both sides of the deposition source 100 and the deposition source nozzle unit 120 to have a protruding shape. The first stage 150, the second stage 160, and the patterning slit sheet 130 are sequentially formed (or located) on the accommodation portions 104-1 in this order.

Here, the first stage 150 is formed to move in X-axis and Y-axis directions so that the first stage 150 aligns the patterning slit sheet 130 in the X-axis and Y-axis directions. That is, the first stage 150 includes a plurality of actuators so that the first stage 150 is moved in the X-axis and Y-axis directions with respect to the upper housing 104.

The second stage 160 is formed to move in a Z-axis direction so as to align the patterning slit sheet 130 in the Z-axis direction. That is, the second stage 160 includes a plurality of actuators and is formed to move in the Z-axis direction with respect to the first stage 150.

The patterning slit sheet 130 is located on the second stage 160. The patterning slit sheet 130 is located on the first stage 150 and the second stage 160 so as to move in the X-axis, Y-axis, and Z-axis directions, and thus, an alignment between the substrate 2 and the patterning slit sheet 130 may be performed.

In addition, the upper housing 104, the first stage 150, and the second stage 160 may guide a flow path of the deposition material 115 such that the deposition material 115 discharged through the deposition source nozzles 121 is not dispersed outside the flow path. That is, the flow path of the deposition material 115 is sealed by the upper housing 104, the first stage 150, and the second stage 160, and thus, the movement of the deposition material 115 in the X-axis and Y-axis directions may be thereby concurrently or simultaneously guided.

The source shutter 141 may be located between the patterning slit sheet 130 and the deposition source 110. The source shutter 141 may function to block the deposition material 115 that is discharged from the deposition source 110. This will be described in detail with reference to FIG. 5.

Although not illustrated, a shielding member (not shown) may be further located so as to prevent an organic material from being deposited on a non-film-forming region of the substrate 2 in the deposition unit 100. The shielding member moves together with the substrate 2 while the shielding member covers an edge portion of the substrate 2, so that the non-film-forming region of the substrate 2 is covered, and by doing so, it is possible to prevent the organic material from being deposited on the non-film-forming region of the substrate 2, without using a separate component.

Also, although not illustrated, a plurality of source shutter driving units (not shown) may be further arranged in the deposition unit 100 so as to move the source shutters 141, respectively. Here, each of the source shutter driving units may include a common motor, a common gear assembly, a cylinder that linearly moves in one direction, and/or the like. However, a type of the source shutter driving unit is not limited to the aforementioned source shutter driving unit, and thus the source shutter driving unit may include any suitable types of devices that may linearly move each of the source shutters 141.

Hereinafter, the conveyer unit 400 that conveys (e.g., transports) the substrate 2, on which the deposition material 115 is to be deposited, is described in more detail. Referring to FIG. 3, the conveyer unit 400 includes the first conveyer unit 410, the second conveyer unit 420, and the transfer unit 430.

The first conveyer unit 410 conveys (e.g., transports) in an in-line manner the transfer unit 430, including a carrier 431 and an electrostatic chuck 432 attached thereto, and the substrate 2 attached to the transfer unit 430 so that an organic layer may be formed on the substrate 2 by the organic layer deposition assembly 100-1.

The second conveyer unit 420 returns to the loading unit 200 the transfer unit 430 from which the substrate 2 has been separated in the unloading unit 300 after one deposition cycle is completed by passing the transfer unit 430 through the deposition unit 100. The second conveyer unit 420 includes a coil 421, roller guides 422, and a charging track 423.

The transfer unit 430 includes the carrier 431 that is conveyed (e.g., transported) along the first conveyer unit 410 and the second conveyer unit 420 and the electrostatic chuck 432 that is combined on a surface of the carrier 431. The substrate 2 is attached to the electrostatic chuck 432.

Hereinafter, each element of the conveyer unit 400 will be described in more detail.

The carrier 431 of the transfer unit 430 will now be described in detail.

The carrier 431 includes a main body part 431a, a magnetic rail 431b, contactless power supply (CPS) modules 431c, a power supply unit 431d, and guide grooves 431e.

The main body part 431a constitutes a base part of the carrier 431 and may be formed of a magnetic material, such as iron. In this regard, due to a magnetic force (e.g., attractive and/or repulsive force) between the main body part 431a and magnetically suspended bearings (e.g., magnetic levitation bearings), the carrier 431 may be maintained spaced apart from guide members 412 by a certain distance.

The guide grooves 431e may be respectively formed at both sides of the main body part 431a and each of the guide grooves 431e may accommodate a guide protrusion of the guide member 412.

The magnetic rail 431b may be formed along a center line of the main body part 431a in a direction in which the main body part 431a proceeds. The magnetic rail 431b of the main body part 431a and a coil 411, which are described below in more detail, may be combined with each other to constitute a linear motor, and the carrier 431 may be conveyed (e.g., transported) in an arrow A direction by the linear motor.

The CPS modules 431c and the power supply unit 431d may be respectively formed on both sides of the magnetic rail 431b in the main body part 431a. The power supply unit 431d includes a battery (e.g., a rechargeable battery) that provides power so that the electrostatic chuck 432 chucks (e.g., fixes or holds) the substrate 2 and maintains operation. The CPS modules 431c are wireless charging modules that charge the power supply unit 431d. For example, the charging track 423 formed in the second conveyer unit 420, which is described below, is connected to an inverter (not shown), and thus, when the carrier 431 is transferred into the second conveyer unit 420, a magnetic field is formed between the charging track 423 and the CPS modules 431c so as to supply power to the CPS modules 431c. The power supplied to the CPS modules 431c is used to charge the power supply unit 431d.

The electrostatic chuck 432 may include an electrode embedded in a main body formed of ceramic, wherein the electrode is supplied with power. The substrate 2 is attached onto a surface of the main body of the electrostatic chuck 432 as a suitable voltage (e.g., a high voltage or a relatively high voltage) is applied to the electrode.

Hereinafter, an operation of the transfer unit 430 is described in more detail.

The magnetic rail 431b of the main body part 431a and the coil 411 may be combined with each other to constitute an operation unit. In this regard, the operation unit may be a linear motor. The linear motor has a small frictional coefficient, little position error, and a high degree (e.g., a very high degree) of position determination, as compared to a conventional slide guide system. As described above, the linear motor may include the coil 411 and the magnetic rail 431b. The magnetic rail 431b is linearly arranged on the carrier 431, and a plurality of coils 411 may be located at an inner side of the chamber 101 by a certain distance so as to face the magnetic rail 431b. Because the magnetic rail 431b is located at the carrier 431, instead of the coil 411, the carrier 431 may be operable without power being supplied thereto. In this regard, the coil 411 may be formed in an atmosphere (ATM) box in an air atmosphere, and the carrier 431 to which the magnetic rail 431b is attached may be moved in the chamber 101 maintained in vacuum.

The organic layer deposition assembly 100-1 of the organic layer deposition apparatus 1 may further include a camera (or cameras) for an aligning process. In more detail, the camera (or cameras) may align in real-time a mark formed at the patterning slit sheet 130 and a mark formed at the substrate 2. Here, the camera (or cameras) is arranged to achieve a visual field in the chamber 101 in which the deposition process is performed. To do so, the camera (or cameras) may be installed in an air atmosphere while formed in a respective camera-housing unit.

Hereinafter, the deposition source 110 and the source shutter 141 of the organic layer deposition apparatus 1 are described in detail.

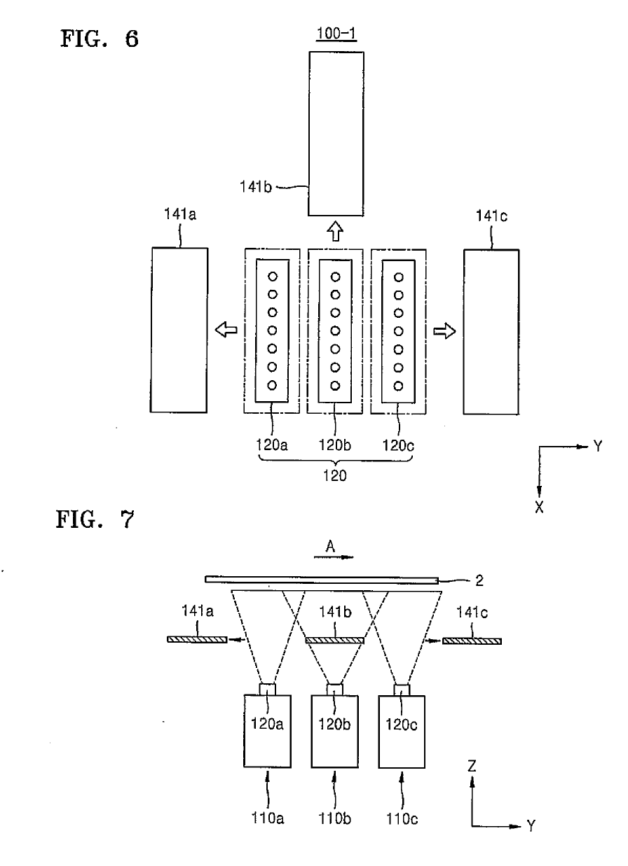

FIG. 4 is a conceptual diagram illustrating the organic layer deposition assembly 100-1 of FIG. 3, showing three deposition sources 110 along the Y-axis direction. Each of the three deposition sources 110 has a corresponding deposition source nozzle unit 120. FIG. 5 is a conceptual diagram illustrating the deposition source 110 and the source shutter 141 of FIG. 3. FIG. 6 is a conceptual diagram illustrating operational statuses of the deposition source 110 and the source shutter 141 of FIG. 5. FIG. 7 is a conceptual diagram illustrating operational statuses of the deposition source 110 and the source shutter 141 of FIG. 5.

Referring to FIGS. 5, 6 and 7, as described above, the organic layer deposition assembly 100-1 may include the deposition source 110 and the source shutter 141. Here, the deposition source 110 may include a first deposition source 110a, a second deposition source 110b, and a third deposition source 110c that are separated from each other along the Y-axis direction.

The first to third deposition sources 110a to 110c may be formed with a similar structure. Here, the first to third deposition sources 110a to 110c may be arranged in parallel with each other. In more detail, the second deposition source 110b may be separated from the first deposition source 110a, and the third deposition source 110c may be separated from the second deposition source 110b.

The source shutter 141 may be further arranged between the patterning slit sheet 130 and the deposition source 110. The source shutter 141 may function to block the deposition material 115 that is output from the deposition source 110.

In more detail, the source shutter 141 may include a first source shutter 141a that is positioned above the first deposition source 110a, a second source shutter 141b that is positioned above the second deposition source 110b, and a third source shutter 141c that is positioned above the third deposition source 110c. Here, the first to third source shutters 141a to 141c may be located on a same virtual plane or different virtual planes. Hereinafter, for convenience of description, it is assumed that the first to third source shutters 141a to 141c are located on the same virtual plane.

The first to third source shutters 141a to 141c may move in different directions. In more detail, the first source shutter 141a may move in a left direction (an opposite direction of the direction A along the Y-axis) in FIG. 5, the second source shutter 141b may move in one direction along the X-axis in FIG. 5 or may move in an opposite direction along the X-axis in FIG. 5, and the third source shutter 141c may move in a right direction (e.g., the direction A) along the Y-axis in FIG. 5. In more detail, the first source shutter 141a and the third source shutter 141c may move in opposite directions, and the second source shutter 141b may move in a direction perpendicular to the directions in which the first source shutter 141a and the third source shutter 141c move.

When the organic layer deposition apparatus 1 initiates driving, in order to prevent denaturation of the deposition material 115, such as an organic material, the organic layer deposition apparatus 1 maintains a temperature until the deposition material 115 is used, without frequently turning on or off the deposition source 110. In this case, during a deposition standby mode that is a status before the organic layer deposition apparatus 1 performs deposition on another substrate after the organic layer deposition apparatus 1 performs deposition on the substrate 2, the deposition material 115 is continuously discharged into the chamber 101 via the patterning slit sheet 130, such that the deposition material 115 is accumulated on the patterning slit sheet 130, thus, it is desirable to block this accumulation.

To do so, the first to third source shutters 141a to 141c are positioned between the deposition sources 110a, 110b, and 110c, and the patterning slit sheet 130 in the chamber 101, thereby blocking the deposition material 115 discharged from the first to third deposition sources 110a to 110c. As described above, when the first to third source shutters 141a to 141c are interposed between the first to third deposition sources 110a to 110c and the patterning slit sheet 130, respectively, it is possible to reduce or minimize the amount of deposition material 115 that is discharged from the deposition source 110 that reaches other regions including the patterning slit sheet 130 in the chamber 101.

As illustrated in FIG. 5, when the substrate 2 does not pass through the organic layer deposition assembly 100-1, the first to third source shutters 141a to 141c screen the first to third deposition sources 110a to 110c, so that the deposition material 115 that is discharged from the first to third deposition sources 110a to 110c does not reach the patterning slit sheet 130.

As illustrated in FIG. 7, when the substrate 2 enters into the organic layer deposition assembly 100-1, the first to third source shutters 141a to 141c that screen the first to third deposition sources 110a to 110c move, and thus, a flow path of the deposition material 115 is opened, and the deposition material 115 that is discharged from the first to third deposition sources 110a to 110c passes through the patterning slit sheet 130 and then is deposited on the substrate 2.

For example, as described above, the first source shutter 141a may open the first deposition source 110a by moving in the left direction in FIG. 5. Also, as described above, the second source shutter 141b may open the second deposition source 110b by moving in one of the opposite directions along the X-axis or in the Y-axis direction. As described above, the third source shutter 141c may open the third deposition source 110c by moving in the right direction in FIG. 5.

When the aforementioned procedure is completed, the first source shutter 141a may move from the left direction toward the right direction in FIG. 5 so as to screen the deposition material 115 discharged from the first deposition source 110a. Also, the second source shutter 141b may move from the X-axis direction toward a direction opposite to the X-axis direction in FIG. 5 or may move from a direction opposite to the X-axis direction toward the X-axis direction in FIG. 5 so as to screen the deposition material 115 discharged from the second deposition source 110b. Here, the X-axis direction in FIG. 5 is the direction indicated by the arrow and marked by the reference character X. The third source shutter 141c may move from the right direction toward the left direction in FIG. 5 so as to screen the deposition material 115 discharged from the third deposition source 110c. Here, the first to third source shutters 141a to 141c move in the aforementioned manner by the source shutter driving units, respectively. While the deposition material 115 is deposited in the organic layer deposition apparatus 1, a large amount of the deposition material 115 is deposited on the first to third source shutters 141a to 141c. In this regard, when a large amount of the deposition material 115 is deposited, the deposition material 115 drops due to its weight. The dropped deposition material 115 functions as a particle, i.e., an impurity in the chamber 101, and also, when the deposition material 115 drops to the deposition source 110, the dropped deposition material 115 affects film-forming uniformity, so that a product quality deteriorates. Moreover, when a dropping occurs because a large amount of the deposition material 115 is deposited on the first to third source shutters 141a to 1410, it is difficult to operate equipment such that an equipment operating rate and production capability may deteriorate.

In order to solve the aforementioned problems, as described above, the first to third source shutters 141a and 141c may move in different directions so that the dropping of the deposition material 115 may be reduced or prevented. In more detail, the deposition material 115 including different types of materials may be vaporized in the first to third deposition sources 110a to 110c and then may be externally discharged. Here, because different types of materials of the deposition material 115 may be deposited on the first to third source shutters 141a to 141c, the first to third source shutters 141a to 141c may move in the different directions so as to prevent themselves from moving above the wrong deposition source 110. By doing so, the dropping of the deposition material 115 is prevented in the organic layer deposition apparatus 1, so that a product quality, an equipment operating rate, and productivity may be improved.

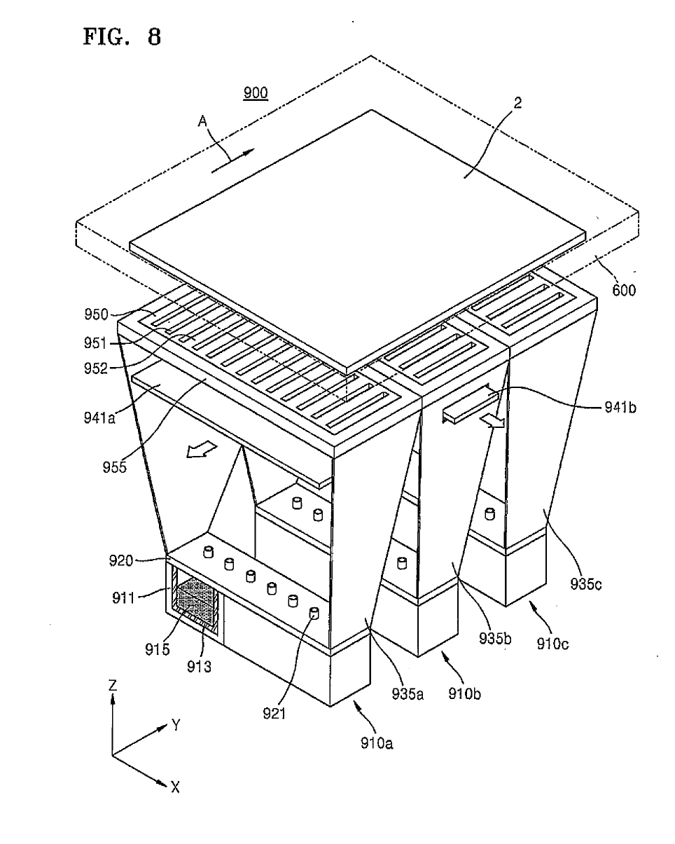

FIG. 8 is a schematic perspective view of an organic layer deposition assembly 900 according to another embodiment of the present invention.

Referring to FIG. 8, the organic layer deposition assembly 900 includes a deposition source 910 (e.g., 910a, 910b, or 910c), a deposition source nozzle unit 920, and a patterning slit sheet 950. Also, the organic layer deposition assembly 900 further includes a source shutter (e.g., 941a or 941b).

The deposition source 910 includes a crucible 911 that is filled with a deposition material 915 and a heater 913 that heats the crucible 911 so as to vaporize the deposition material 915 included in the crucible 911 toward the deposition source nozzle unit 920. The deposition source nozzle unit 920 is located at a side of the deposition source 910, and a plurality of deposition source nozzles 921 are formed on the deposition source nozzle unit 920 along an X-axis direction.

Here, the deposition source 910 may include a first deposition source 910a, a second deposition source 910b, and a third deposition source 910c. The first deposition source 910a, the second deposition source 910b, and the third deposition source 910c may externally discharge different types of deposition materials.

Here, the patterning slit sheet 950 and a frame 955 are further located between the deposition source 910 and the substrate 2, and a plurality of patterning slits 951 are formed at the patterning slit sheet 950 along the X-axis direction. The deposition source 910, the deposition source nozzle unit 920, and the patterning slit sheet 950 are combined by using connection members 935 (935a, 935b, or 935c).

The present embodiment is different from the previous embodiments in that arrangements of the deposition source nozzles 921 at the deposition source nozzle unit 920 are changed. Hereinafter, the difference is described as below.

The deposition source nozzle unit 920 is located at a side of the deposition source 910 so as face the substrate 2. The deposition source nozzles 921 are formed on the deposition source nozzle unit 920 along the X-axis direction. The deposition material 915 that has been vaporized in the deposition source 910 passes through the deposition source nozzle unit 920 and then moves toward the substrate 2 that is a deposition target.

Also, the source shutter may be arranged between the connection members 935. As described above, the source shutter may include a first source shutter 941a, a second source shutter 941b, and a third source shutter (not shown).

Because the first source shutter 941a, the second source shutter 941b, and the third source shutter operate while being formed with the same or similar structure as that of the first to third source shutters 141a to 141c (see for example, FIG. 5), the detailed descriptions thereof are omitted here. In a case of the second source shutter 941b, the second source shutter 941b may move to pass through a second connection member 935b.

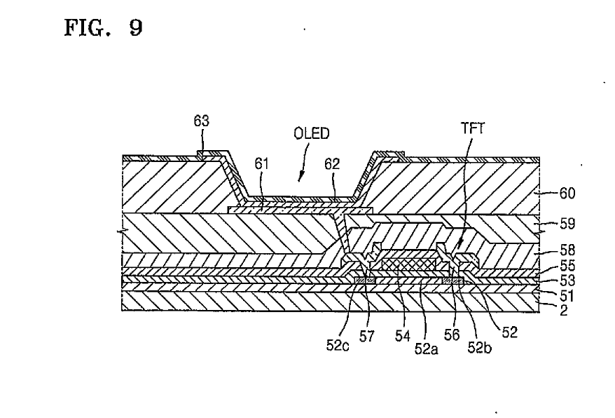

FIG. 9 is a cross-sectional view of an active matrix-type organic light-emitting display device manufactured using the organic layer deposition apparatus 1, according to an embodiment of the present invention.

Referring to FIG. 9, the active matrix organic light-emitting display device according to the current embodiment is formed on the substrate 2. The substrate 2 may be formed of a transparent material, for example, glass, plastic, or metal. An insulating layer 51, such as a buffer layer, is formed on an entire surface of the substrate 2.

A thin film transistor (TFT) and an organic light-emitting diode (OLED) are located on the insulating layer 51, as illustrated in FIG. 9.

A semiconductor active layer 52 is formed on an upper surface of the insulating layer 51 in a set or predetermined pattern. A gate insulating layer 53 is formed to cover the semiconductor active layer 52. The semiconductor active layer 52 may include a p-type or n-type semiconductor material.

A gate electrode 54 of the TFT is formed on (or over) a region of the gate insulating layer 53 corresponding to a channel region 52a of the semiconductor active layer 52. An interlayer insulating layer 55 is formed to cover the gate electrode 54. The interlayer insulating layer 55 and the gate insulating layer 53 are etched by, for example, dry etching, to form contact holes exposing parts of the semiconductor active layer 52.

Source/drain electrodes 56 and 57 are formed on the interlayer insulating layer 55 to contact source/drain regions 52b and 52c, respectively, of the semiconductor active layer 52 through the respective contact holes. A protective layer (e.g., a passivation layer) 58 is formed to cover the source/drain electrodes 56 and 57, and is etched to expose a part of one of the source/drain electrodes 56 and 57. An insulating layer 59 may be further formed on the protective layer 58 so as to planarize the protective layer 58.

In addition, the OLED displays set or predetermined image information by emitting red, green, or blue light according to current. The OLED includes a first electrode 61 located on the protective layer 58 (and the insulating layer 59 when it is formed). The first electrode 61 is electrically connected to the exposed source/drain electrode 57 of the TFT.

A pixel-defining layer 60 is formed to cover the first electrode 61. An opening is formed in the pixel-defining layer 60, and an organic layer 62 including an emission layer (EML) is formed in a region defined by the opening. A second electrode 63 is formed on the organic layer 62.

The pixel-defining layer 60, which defines individual pixels, may be formed of an organic material. The pixel-defining layer 60 also planarizes the surface of a region of a substrate 2 in which the first electrode 61 is formed, and in particular, a surface of the insulating layer 59.

The first electrode 61 and a second electrode 63 are insulated from each other, and respectively apply voltages of opposite polarities to an organic layer 62 to induce light emission.

The organic layer 62 including an EML may be formed of a low-molecular weight organic material or a high-molecular weight organic material. When a low-molecular weight organic material is used, the organic layer 62 may have a single or multi-layer structure including a hole injection layer (HIL), a hole transport layer (HTL), the EML, an electron transport layer (ETL), and/or an electron injection layer (EIL). Non-limiting examples of available organic materials may include copper phthalocyanine (CuPc), N,N′-di(naphthalene-1-yl)-N,N′-diphenyl-benzidine (NPB), and tris-8-hydroxyquinoline aluminum (Alq₃).

The organic layer 62 including the EML may be formed using the organic layer deposition apparatus 1 illustrated in FIG. 1. That is, an organic layer deposition apparatus including a deposition source that discharges a deposition material, a deposition source nozzle unit that is located at a side of the deposition source and includes a plurality of deposition source nozzles formed therein, and a patterning slit sheet that faces the deposition source nozzle unit and includes a plurality of patterning slits formed therein is located spaced apart by a set or predetermined distance from a substrate on which the deposition material is to be deposited. In addition, the deposition material discharged from the organic layer deposition apparatus 1 (refer to FIG. 1) is deposited on the substrate 2 (refer to FIG. 1) while the organic layer deposition apparatus 1 and the substrate 2 are moved relative to each other.

After the organic layer 62 is formed, the second electrode 63 may be formed by the same deposition method as used to form the organic layer 62.

The first electrode 61 may function as an anode, and the second electrode 63 may function as a cathode. Alternatively, the first electrode 61 may function as a cathode, and the second electrode 63 may function as an anode. The first electrode 61 may be patterned to correspond to individual pixel regions, and the second electrode 63 may be formed to cover all the pixels.

The first electrode 61 may be formed as a transparent electrode or a reflective electrode. Such a transparent electrode may be formed of indium tin oxide (ITO), indium zinc oxide (IZO), zinc oxide (ZnO), or indium oxide (In₂O₃). Such a reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, or In₂O₃ on the reflective layer. The first electrode 61 may be formed by forming a layer by, for example, sputtering, and then patterning the layer by, for example, photolithography.

The second electrode 63 may also be formed as a transparent electrode or a reflective electrode. In one embodiment, when the second electrode 63 is formed as a transparent electrode, the second electrode 63 may be used as a cathode. To this end, such a transparent electrode may be formed by depositing a metal having a low work function, such as lithium (Li), calcium (Ca), lithium fluoride/calcium (LiF/Ca), lithium fluoride/aluminum (LiF/AI), aluminum (Al), silver (Ag), magnesium (Mg), or a compound thereof on a surface of the organic layer 62 and forming an auxiliary electrode layer or a bus electrode line thereon from ITO, IZO, ZnO, In₂O₃, or the like. When the second electrode 63 is formed as a reflective electrode, the reflective layer may be formed by depositing Li, Ca, LiF/Ca, LiF/Al, Al, Ag, Mg, or a compound thereof on the entire surface of the organic layer 63. The second electrode 63 may be formed using the same deposition method as used to form the organic layer 62 described above.

The organic layer deposition apparatuses according to the embodiments of the present invention described above may be applied to form an organic layer or an inorganic layer of an organic TFT, and to form layers from various materials.

According to the one or more embodiments of the present invention, it is possible to prevent the deposition material that has been deposited on the source shutter from dropping to another deposition source, such that the other deposition source is clogged or mixed with different deposition materials to badly affect a characteristic of a manufactured product. Also, according to the one or more embodiments of the present invention, it is possible to reduce or minimize that the deposition nozzles are clogged or organic materials are mixed due to dropping of the deposition material of the source shutter to the deposition source, so that a loss due to interruption of facilities may be reduced or minimized.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. An organic layer deposition apparatus comprising:
a conveyer unit comprising a transfer unit configured to be attached to a substrate and to move along with the substrate, a first conveyer unit configured to move in a first direction the transfer unit to which the substrate is attached, and a second conveyer unit configured to move in a direction opposite to the first direction the transfer unit from which the substrate is separated after deposition has been completed; and
a deposition unit comprising one or more organic layer deposition assemblies configured to deposit an organic layer on the substrate that is attached to the transfer unit,
wherein each of the one or more organic layer deposition assemblies comprises:
a plurality of deposition sources configured to discharge a deposition material;
a deposition source nozzle unit at a side of each of the plurality of deposition sources and comprising a plurality of deposition source nozzles;
a patterning slit sheet facing the deposition source nozzle unit and comprising a plurality of patterning slits; and
a plurality of source shutters separated from the plurality of deposition sources, respectively, and configured to block a deposition material that is vaporized in each of the plurality of deposition sources, and
wherein the plurality of source shutters are configured to move in different directions, thereby blocking or allowing to pass the deposition material that is vaporized in each of the plurality of deposition sources.

2. The organic layer deposition apparatus of claim 1, wherein the plurality of deposition sources comprise:
a first deposition source;
a second deposition source that is separated from the first deposition source; and
a third deposition source that is separated from the second deposition source.

3. The organic layer deposition apparatus of claim 2, wherein the plurality of source shutters comprise:
a first source shutter that is configured to be located above the first deposition source;
a second source shutter that is configured to be located above the second deposition source; and
a third source shutter that is configured to be located above the third deposition source.

4. The organic layer deposition apparatus of claim 3, wherein the first source shutter and the third source shutter are movable in opposite directions.

5. The organic layer deposition apparatus of claim 3, wherein the second source shutter is movable in a direction perpendicular to a movement direction of at least one of the first source shutter or the third source shutter.

6. The organic layer deposition apparatus of claim 1, wherein the plurality of source shutters are configured to move in a space between the plurality of deposition sources and the patterning slit sheet.

7. The organic layer deposition apparatus of claim 1, wherein the deposition material that is discharged from the plurality of deposition sources passes through the patterning slit sheet and then is deposited to form a pattern on the substrate.

8. The organic layer deposition apparatus of claim 1, wherein the patterning slit sheet is smaller than the substrate in the first direction.

9. The organic layer deposition apparatus of claim 1, wherein the first conveyer unit and the second conveyer unit pass through the deposition unit.

10. The organic layer deposition apparatus of claim 1, wherein the first conveyer unit and the second conveyer unit are respectively arranged above and below in parallel to each other.

11. The organic layer deposition apparatus of claim 1, wherein the transfer unit is configured to cyclically move between the first conveyer unit and the second conveyer unit, and to keep the substrate attached thereto, spaced apart from the organic layer deposition assembly while being transferred by the first conveyer unit.

12. A method of manufacturing an organic light-emitting display apparatus by using an organic layer deposition apparatus for forming an organic layer on a substrate, the method comprising:
transporting, into a chamber, a transfer unit to which the substrate is attached, by using a first conveyer unit passing through the chamber;
forming an organic layer by depositing a deposition material discharged from an organic layer deposition assembly on the substrate while the substrate is moved relative to the organic layer deposition assembly with the organic layer deposition assembly in the chamber being spaced apart from the substrate; and
transporting the transfer unit from which the substrate is separated, by using a second conveyer unit passing through the chamber,
wherein the organic layer deposition assembly comprises:
a plurality of deposition sources for discharging a deposition material; and
a plurality of source shutters separated from the plurality of deposition sources, respectively, and blocking a deposition material that is vaporized in each of the plurality of deposition sources, and
wherein, in the forming of the organic layer, the plurality of source shutters move in different directions, whereby the plurality of source shutters block or allow to pass the deposition material that is vaporized in each of the plurality of deposition sources.

13. The method of claim 12, wherein the organic layer deposition assembly further comprises:
a deposition source nozzle unit at a side of each of the plurality of deposition sources and comprising a plurality of deposition source nozzles; and
a patterning slit sheet facing the deposition source nozzle unit and comprising a plurality of patterning slits.

14. The method of claim 13, wherein the deposition material that is discharged from the plurality of deposition sources passes through the patterning slit sheet and then is deposited to form a pattern on the substrate.

15. The method of claim 13, wherein the plurality of source shutters move in a space between the plurality of deposition sources and the patterning slit sheet.

16. The method of claim 12, wherein the plurality of source shutters are movable to prevent the deposition material, which is vaporized in each of the plurality of deposition sources, from being deposited on the substrate.

17. The method of claim 12, wherein the plurality of deposition sources comprise:
a first deposition source;
a second deposition source that is separated from the first deposition source; and
a third deposition source that is separated from the second deposition source.

18. The method of claim 17, wherein the plurality of source shutters comprise:
a first source shutter that is configured to be located above the first deposition source;
a second source shutter that is configured to be located above the second deposition source; and
a third source shutter that is configured to be located above the third deposition source.

19. The method of claim 18, wherein the first source shutter and the third source shutter are movable in opposite directions.

20. The method of claim 18, wherein the second source shutter is movable in a direction perpendicular to a movement direction of at least one of the first source shutter or the third source shutter.
